(19) United States
(12) Patent Application Publication
(10) Pub. No.: US 2024/0096870 A1
(43) Pub. Date: Mar. 21, 2024

(54) SEMICONDUCTOR INTEGRATED CIRCUIT DEVICE

(71) Applicant: Socionext Inc., Kanagawa (JP)

(72) Inventor: Toshihiro NAKAMURA, Yokohama-shi (JP)

(21) Appl. No.: 18/526,546

(22) Filed: Dec. 1, 2023

Related U.S. Application Data
(63) Continuation of application No. PCT/JP2021/021260, filed on Jun. 3, 2021.

(51) Int. Cl. H01L 27/02; H01L 23/528

(52) U.S. Cl. CPC H01L 27/0248; H01L 23/5286

(57) ABSTRACT

In a semiconductor integrated circuit device, a first power line extends in an X direction in an IO region and is formed in a first interconnect layer. A second power line extends in the X direction in a core region. A third power line extends in a Y direction, is formed in a second interconnect layer located below the first interconnect layer, and is connected to the first and second power lines. The third power line overlaps an external connection pad in planar view and is placed between adjacent interconnects in the X direction.

### CROSS-REFERENCE TO RELATED APPLICATIONS

This is a continuation of International Application No. PCT/JP2021/021260 filed on Jun. 3, 2021. The entire disclosure of this application is incorporated by reference herein.

### BACKGROUND

The present disclosure relates to a semiconductor integrated circuit device having a core region and an IO region in which input/output cells (IO cells) are arranged.

In recent semiconductor integrated circuits, with the advancement in miniaturization, the interconnect resistance is increasing and the power supply voltage is becoming lower. This causes problems such as decrease in electrostatic discharge (ESD) tolerance, instability of circuit operation caused by a power supply voltage drop, and a malfunction of a circuit.

In order to prevent or reduce the power supply voltage drop and improve the ESD tolerance in a semiconductor integrated circuit device, it is preferable to enhance power lines to reduce the resistance value of the power lines. Enhanced power lines also prevent or reduce the occurrence of electromigration in power lines. Moreover, enhanced power lines prevent or reduce large noise that may occur at the time of simultaneous changes of signals output from signal IO cells. It is however preferable that enhancement of power lines should be achievable without causing an increase in the area of the semiconductor integrated circuit device.

An objective of the present disclosure is providing a configuration capable of enhancing power lines while preventing or reducing an increase in area in a semiconductor integrated circuit device having an arrangement of IO cells.

### SUMMARY

According to the first mode of the present disclosure, a semiconductor integrated circuit device includes: a chip; a core region provided on the chip; an IO region provided on the chip between the core region and an outer periphery of the chip; an IO cell row provided in the IO region and constituted by a plurality of IO cells including first and second IO cells arranged in line in a first direction, the first direction being a direction along the outer periphery; a first power line extending in the first direction in the IO region, formed in a first interconnect layer and supplying first power; a second power line extending in the first direction in the core region and supplying the first power; a third power line extending in a second direction vertical to the first direction, formed in a second interconnect layer located below the first interconnect layer and connected to the first and second power lines; first and second external connection pads respectively corresponding to the first and second IO cells; a first interconnect connecting the first IO cell and the first external connection pad, formed in the second interconnect layer; and a second interconnect connecting the second IO cell and the second external connection pad, formed in the second interconnect layer, wherein the third power line overlaps the first external connection pad in planar view and is placed between the first interconnect and the second interconnect in the first direction.

According to the above mode, in the semiconductor integrated circuit device, the first power line supplying first power extends in the first direction along the outer periphery of the chip in the IO region and is formed in the first interconnect layer. The second power line supplying the first power extends in the first direction in the core region. The third power line extends in the second direction vertical to the first direction, is formed in the second interconnect layer below the first interconnect layer, and is connected to the first and second power lines. That is, since the first power line in the IO region and the second power line in the core region are connected by the third power line extending in the second direction, enhancement of power lines supplying the first power is achieved. Also, the third power line overlaps the first external connection pad in planar view, and is placed between adjacent interconnects, each connecting the IO cell and the external connection pad, in the first direction. Therefore, the placement of the third power line does not cause increase in the area of the semiconductor integrated circuit device.

According to the second mode of the present disclosure, a semiconductor integrated circuit device includes: a chip; a core region provided on the chip; an IO region provided on the chip between the core region and an outer periphery of the chip; an IO cell row provided in the IO region and constituted by a plurality of IO cells including a first IO cell arranged in line in a first direction, the first direction being a direction along the outer periphery; a first power line extending in the first direction in the IO region, formed in a first interconnect layer and supplying first power; a second power line extending in the first direction in the core region and supplying the first power; a third power line extending in a second direction vertical to the first direction, formed in a second interconnect layer located below the first interconnect layer and connected to the first and second power lines; a fourth power line extending in the second direction, formed in the second interconnect layer and connected to the first and second power lines; a first external connection pad corresponding to the first IO cell; and a first interconnect connecting the first IO cell and the first external connection pad, formed in the second interconnect layer, wherein the third and fourth power lines overlap the first external connection pad in planar view, and the first interconnect is placed between the third power line and the fourth power line in the first direction.

According to the above mode, in the semiconductor integrated circuit device, the first power line supplying first power extends in the first direction along the outer periphery of the chip in the IO region and is formed in the first interconnect layer. The second power line supplying the first power extends in the first direction in the core region. The third and fourth power lines extend in the second direction vertical to the first direction, are formed in the second interconnect layer below the first interconnect layer, and are connected to the first and second power lines. That is, since the first power line in the IO region and the second power line in the core region are connected by the third and fourth power lines extending in the second direction, enhancement of power lines supplying the first power is achieved. Also, the third and fourth power lines overlap the first external connection pad in planar view, and an interconnect connecting the IO cell and the external connection pad is placed between the third and fourth power lines in the first direction. Therefore, the placement of the third and fourth power lines does not cause increase in the area of the semiconductor integrated circuit device.

According to the third mode of the present disclosure, a semiconductor integrated circuit device includes: a chip; a core region provided on the chip; an IO region provided on the chip between the core region and an outer periphery of the chip; a peripheral region provided on the chip between the IO region and the outer periphery; an IO cell row provided in the IO region and constituted by a plurality of IO cells including first and second IO cells arranged in line in a first direction, the first direction being a direction along the outer periphery; a first power line extending in the first direction in the IO region, formed in a first interconnect layer and supplying first power; a second power line extending in the first direction in the peripheral region and supplying the first power; a third power line extending in a second direction vertical to the first direction, formed in a second interconnect layer located below the first interconnect layer and connected to the first and second power lines; first and second external connection pads respectively corresponding to the first and second IO cells; a first interconnect connecting the first IO cell and the first external connection pad, formed in the second interconnect layer; and a second interconnect connecting the second IO cell and the second external connection pad, formed in the second interconnect layer, wherein the third power line overlaps the first external connection pad in planar view and is placed between the first interconnect and the second interconnect in the first direction.

According to the above mode, in the semiconductor integrated circuit device, the first power line supplying first power extends in the first direction along the outer periphery of the chip in the IO region and is formed in the first interconnect layer. The second power line supplying the first power extends in the first direction in the peripheral region provided between the IO region and the outer periphery of the chip. The third power line extends in the second direction vertical to the first direction, is formed in the second interconnect layer below the first interconnect layer, and is connected to the first and second power lines. That is, since the first power line in the IO region and the second power line in the peripheral region are connected by the third power line extending in the second direction, enhancement of power lines supplying the first power is achieved. Also, the third power line overlaps the first external connection pad in planar view, and is placed between adjacent interconnects, each connecting the IO cell and the external connection pad, in the first direction. Therefore, the placement of the third power line does not cause increase in the area of the semiconductor integrated circuit device.

According to the fourth mode of the present disclosure, a semiconductor integrated circuit device includes: a chip; a core region provided on the chip; an IO region provided on the chip between the core region and an outer periphery of the chip; a peripheral region provided on the chip between the IO region and the outer periphery; an IO cell row provided in the IO region and constituted by a plurality of IO cells including a first IO cell arranged in line in a first direction, the first direction being a direction along the outer periphery; a first power line extending in the first direction in the IO region, formed in a first interconnect layer and supplying first power; a second power line extending in the first direction in the peripheral region and supplying the first power; a third power line extending in a second direction vertical to the first direction, formed in a second interconnect layer located below the first interconnect layer and connected to the first and second power lines; a fourth power line extending in the second direction, formed in the second interconnect layer and connected to the first and second power lines; a first external connection pad corresponding to the first IO cell; and a first interconnect connecting the first IO cell and the first external connection pad, formed in the second interconnect layer, wherein the third and fourth power lines overlap the first external connection pad in planar view, and the first interconnect is placed between the third power line and the fourth power line in the first direction.

According to the above mode, in the semiconductor integrated circuit device, the first power line supplying first power extends in the first direction along the outer periphery of the chip in the IO region and is formed in the first interconnect layer. The second power line supplying the first power extends in the first direction in the peripheral region provided between the IO region and the outer periphery of the chip. The third and fourth power lines extend in the second direction vertical to the first direction, are formed in the second interconnect layer below the first interconnect layer, and are connected to the first and second power lines. That is, since the first power line in the IO region and the second power line in the peripheral region are connected by the third and fourth power lines extending in the second direction, enhancement of power lines supplying the first power is achieved. Also, the third and fourth power lines overlap the first external connection pad in planar view, and an interconnect connecting the IO cell and the external connection pad is placed between the third and fourth power lines in the first direction. Therefore, the placement of the third and fourth power lines does not cause increase in the area of the semiconductor integrated circuit device.

According to the present disclosure, in a semiconductor integrated circuit device, enhancement of power lines can be achieved without causing an increase in area.

### BRIEF DESCRIPTION OF THE DRAWINGS

FIG. 1 is a plan view schematically showing the entire configuration of a semiconductor integrated circuit device according to the first embodiment.

FIG. 2 is a plan view showing a configuration example according to the first embodiment.

FIG. 3 is a plan view showing a configuration example according to an alteration of the first embodiment.

FIG. 4 is a plan view schematically showing the entire configuration of a semiconductor integrated circuit device according to the second embodiment.

FIG. 5 is a plan view showing a configuration example according to the second embodiment.

FIG. 6 is a plan view showing a configuration example according to an alteration of the second embodiment.

FIG. 7 is a plan view showing a configuration example according to another embodiment.

FIG. 8 is a plan view showing a configuration example according to yet another embodiment.

### DETAILED DESCRIPTION

Embodiments of the present disclosure will be described hereinafter with reference to the accompanying drawings.

### First Embodiment

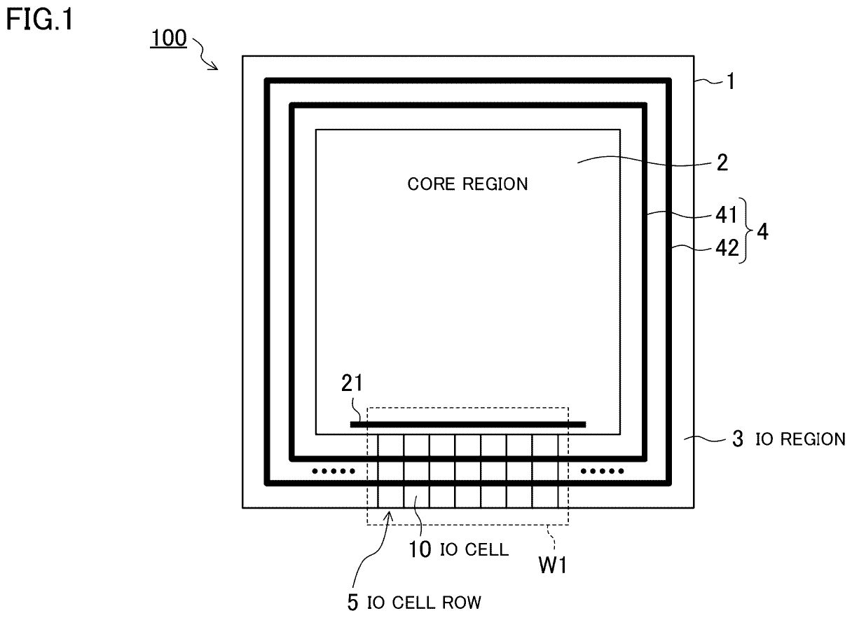

FIG. 1 is a plan view schematically showing the entire configuration of a semiconductor integrated circuit device (semiconductor chip) according to the first embodiment. A semiconductor integrated circuit device 100 shown in FIG. 1 includes, on a chip 1: a core region 2 in which internal core circuits are formed; and an IO region 3 in which interface circuits (IO circuits) are formed. The IO region 3 lies between the core region 2 and the outer periphery of the chip 1. In the IO region 3, an IO cell row 5 is provided to run along the outer periphery of the chip 1. Although illustration is simplified in FIG. 1, a plurality of IO cells 10 constituting interface circuits are arranged in line in the IO cell row 5.

The IO cells 10 here include: a signal IO cell that conducts input, output, or input/output of signals; an IO power IO cell for supplying power (power supply voltage VDDIO) mainly to the IO region 3; a VSS IO cell for supplying a ground potential (power supply voltage VSS); and a core power IO cell for supplying power (power supply voltage VDD) mainly to the core region 2. VDDIO is higher than VDD: e.g., VDDIO is 1.8 V and VDD is 0.9 V. Note herein that the IO power IO cell, the VSS IO cell, and the core power IO cell are collectively called power IO cells as appropriate.

In the IO region 3, provided are power lines 4 extending in the direction in which the IO cells 10 are arranged. The power lines 4 here include power lines 41 and 42 supplying VSS. Note that, while the power lines 41 and 42 are each illustrated as a single line in FIG. 1, they may actually be each constituted by a plurality of lines as will be described later. Also, the power lines 4 include a power line supplying VDDIO and a power line supplying VDD in some cases.

Also, a power line 21 extending in the direction in which the IO cells 10 are arranged is provided in a portion of the core region 2 near the IO region. The power line 21 here supplies VSS. While the power line 21 is illustrated as a single line, it may be constituted by a plurality of lines. Also, while illustration is omitted in FIG. 1, a plurality of external connection pads are placed in the semiconductor integrated circuit device 100.

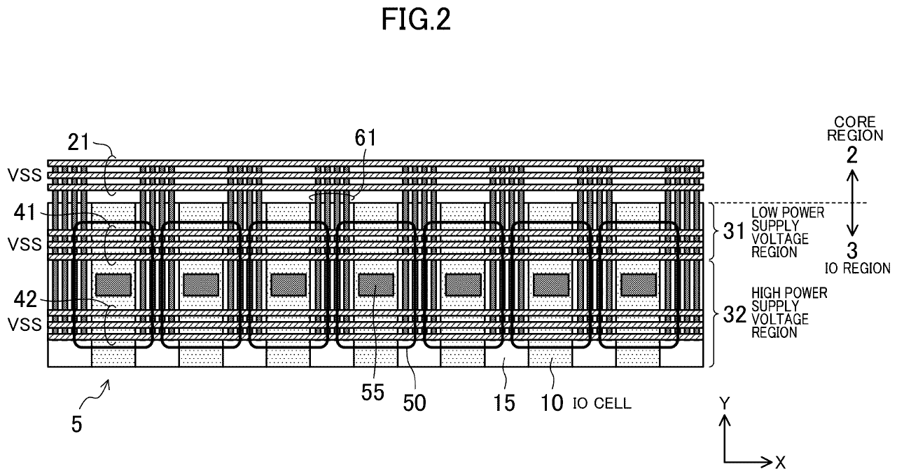

FIG. 2 is a plan view showing a configuration example of the IO region 3 of the semiconductor integrated circuit device 100 of this embodiment, which is an enlarged view of a part W1 of FIG. 1. Note that, in FIG. 2, illustration of the internal configuration of each IO cell 10, signal lines, and the like is omitted.

In FIG. 2, the IO cell row 5 includes a plurality of IO cells 10 arranged in line in an X direction (horizontal direction in the figure; the direction along the outer periphery of the chip 1, which corresponds to the first direction). The IO cells 10 are arranged with a gap 15 between the adjacent cells in the X direction. The IO cells 10 include signal IO cells and power IO cells. It is assumed here that the IO cells 10 have the same width, i.e., size in the X direction and also have the same height, i.e., size in a Y direction (vertical direction in the figure, which corresponds to the second direction). Note that the sizes are not limited to these, but the widths of the IO cells 10 do not necessarily need to be the same, and the height of the IO cells 10 do not necessarily need to be the same.

The signal IO cells include circuits required to exchange signals with the outside of the semiconductor integrated circuit device 100 or with the core region 2, such as a level shifter circuit, an output buffer circuit, and a circuit for ESD protection, for example. The power IO cells, which supply power fed to the external connection pads to the inside of the semiconductor integrated circuit device 100, include a circuit for ESD protection, for example.

An IO cell generally has: a high power supply voltage region including a circuit for ESD protection and an output buffer for outputting a signal to the outside of the semiconductor integrated circuit device; and a low power supply voltage region including a circuit for inputting/outputting a signal into/from the inside of the semiconductor integrated circuit device. Each of the IO cells 10 in FIG. 2 has a low power supply voltage region 31 and a high power supply voltage region 32 separated in the Y direction. In FIG. 2, the low power supply voltage region 31 is located closer to the core region 2 and the high power supply voltage region 32 is located closer to the chip edge.

External connection pads 50 are placed above the IO cells 10. Each of the external connection pads 50, corresponding to its underlying IO cell 10, is connected to the corresponding IO cell 10 via an interconnect 55. The width, i.e., size in the X direction of the external connection pads 50 is greater than the width of the IO cells 10. Therefore, the gap 15 is provided between the adjacent IO cells 10 so that the IO cells 10 and the external connection pads 50 can be placed in a one-to-one correspondence with each other.

In the IO region 3, the power lines 41 and 42 extending in the X direction are placed. The power lines 41 and 42 are formed in a first interconnect layer made of a single layer or a plurality of layers, and supply VSS. While each of the power lines 41 and 42 is illustrated here as being constituted by three lines, the configuration is not limited to this. The power line 41 is placed in the low power supply voltage region 31 of each IO cell 10, and the power line 42 is placed in the high power supply voltage region 32 of each IO cell 10.

In the core region 2, the power line 21 extending in the X direction is placed. The power line 21 is formed in the same first interconnect layer as the power lines 41 and 42, and supplies VSS. While the power line 21 is illustrated here as being constituted by three lines, the configuration is not limited to this. The power line 21 is connected to transistors in the core region 2. Note that the power line 21 may be formed in an interconnect layer located above or below the first interconnect layer.

A power line 61 extending in the Y direction is placed in each of the gaps 15 between the adjacent IO cells 10 in the IO region 3. The power lines 61 are formed in a second interconnect layer made of a single layer or a plurality of layers, located below the first interconnect layer. While each of the power lines 61 is illustrated here as being constituted by four lines, the configuration is not limited to this. The power lines 61 have overlaps with the external connection pads 50 in planar view. The power lines 61 are connected to the power lines 21, 41, and 42 at their respective intersections. This connection is made through vias or through vias and interconnects.

The interconnects 55 are formed in the same second interconnect layer as the power lines 61. The interconnects 55 connect the corresponding external connection pads 50 and elements such as transistors of the corresponding IO cells 10. Note that the interconnects 55 and the external connection pads 50 may be connected directly or through an interconnect layer other than the second interconnect layer and vias. Similarly, the interconnects 55 and the elements of the IO cells 10 may be connected directly or through an interconnect layer other than the second interconnect layer and vias.

In the configuration of FIG. 2, in the second interconnect layer, the interconnects 55 are placed between the adjacent power lines 61 in the X direction: i.e., each interconnect 55 is interposed between two power lines 61. Also, the power lines 61 are placed between the adjacent interconnects 55 in the X direction: i.e., each power line 61 is interposed between two interconnects 55.

With the configuration of FIG. 2, the following advantages are obtained.

As for VSS power lines, the power line 21 supplying VSS is provided in the core region 2. The power lines 41 and 42 provided in the IO region 3 and the power line 21 in the core region 2 are mutually connected by the power lines 61 extending in the Y direction. With this, enhancement of the VSS power lines is achieved, whereby the resistance value of the VSS power lines can be reduced. In the semiconductor integrated circuit device 100, therefore, the power supply voltage drop can be prevented or reduced, and the ESD tolerance can be improved.

The above enhancement of the power lines is achieved by placing the power lines 61 in the gaps 15 between the adjacent IO cells 10 and connecting the power lines 21, 41, and 42 supplying VSS. Therefore, no increase in the area of the semiconductor integrated circuit device 100 is caused by the placement of the power lines 61.

Also, in the configuration of FIG. 2, a large current flowing to the power line 42 in the high power supply voltage regions 32, in particular, of the IO cells 10 can be passed dispersedly to the power line 21 in the core region 2. Therefore, the occurrence of electromigration in the power line 42 can be prevented or reduced.

Large noise may occur at the time of simultaneous change of signals output from the signal IO cells. By enhancing the power lines as in the configuration of FIG. 2, this problem can be prevented or reduced, and therefore a malfunction of the semiconductor integrated circuit device 100 can be prevented.

Also, in the configuration of FIG. 2, in the IO cells 10, since the power line 41 placed in the low power supply voltage regions 31 and the power line 42 placed in the high power supply voltage regions 32 are mutually connected, power enhancement inside the IO cells 10 is also achieved.

<Alteration>

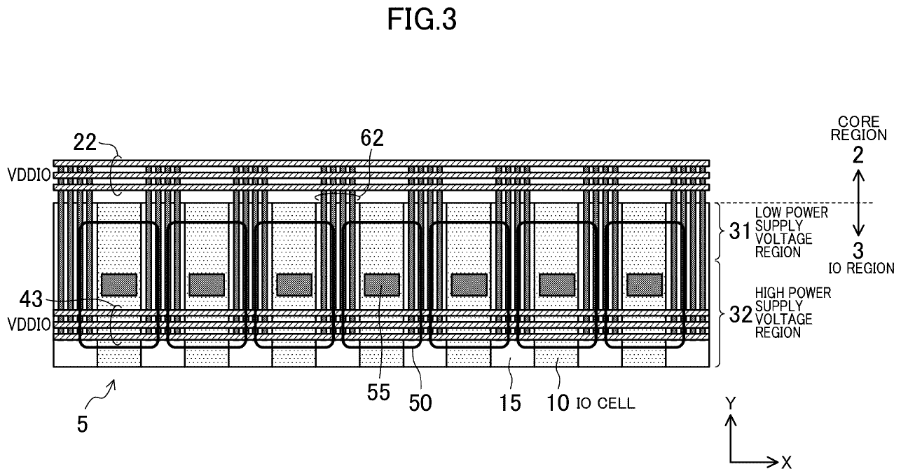

FIG. 3 is a plan view showing a configuration example of the IO region 3 of a semiconductor integrated circuit device 100 according to an alteration of this embodiment. In FIG. 3, power VDDIO is enhanced with a power line in the core region 2.

In the IO region 3, a power line 43 extending in the X direction is placed. The power line 43 is formed in a first interconnect layer made of a single layer or a plurality of layers, and supplies VDDIO. While the power line 43 is illustrated here as being constituted by three lines, the configuration is not limited to this. The power line 43 is placed in the high power supply voltage region 32 of each IO cell 10. Note that no power line supplying VDDIO is placed in the low power supply voltage region 31 since VDDIO is unnecessary in this region.

In the core region 2, a power line 22 extending in the X direction is placed. The power line 22 is formed in the same first interconnect layer as the power line 43, and supplies VDDIO. While the power line 22 is illustrated here as being constituted by three lines, the configuration is not limited to this. Note that the power line 22 may be formed in an interconnect layer located above or below the first interconnect layer.

A power line 62 extending in the Y direction is placed in each of the gaps 15 between the adjacent IO cells 10 in the IO region 3. The power lines 62 are formed in a second interconnect layer made of a single layer or a plurality of layers, located below the first interconnect layer. While each of the power lines 62 is illustrated here as being constituted by four lines, the configuration is not limited to this. The power lines 62 have overlaps with the external connection pads 50 in planar view. The power lines 62 are connected to the power lines 22 and 43 at their respective intersections. This connection is made through vias or through vias and interconnects.

In this alteration, also, similar advantages to those described in the above embodiment are obtained. That is, enhancement of the VDDIO power lines is achieved, whereby the resistance value of the VDDIO power lines can be reduced. In the semiconductor integrated circuit device 100, therefore, the power supply voltage drop can be prevented or reduced, and the ESD tolerance can be improved.

Note that it is also possible to perform both the enhancement of the VSS power lines in the above embodiment and the enhancement of the VDDIO power lines in this alteration together.

### Second Embodiment

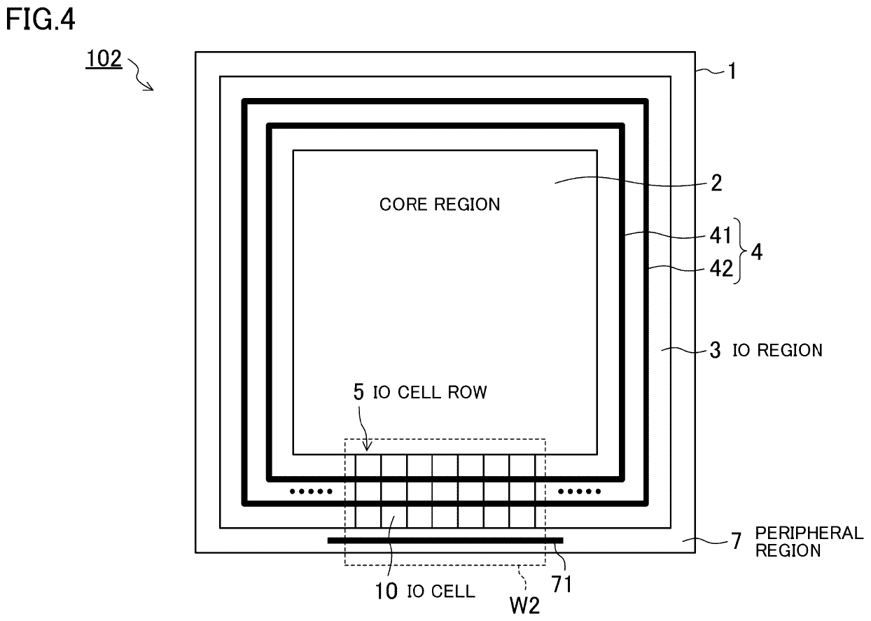

FIG. 4 is a plan view schematically showing the entire configuration of a semiconductor integrated circuit device (semiconductor chip) according to the second embodiment. Note that, in this embodiment, components in common with the first embodiment are denoted by the same reference characters, and description of such components is simplified or omitted in some cases.

A semiconductor integrated circuit device 102 shown in FIG. 4 includes, on a chip 1: a core region 2 in which internal core circuits are formed; an IO region 3 in which interface circuits (IO circuits) are formed; and a peripheral region 7. The peripheral region 7 lies on the outer side of the IO region 3, i.e., between the IO region 3 and the outer periphery of the chip 1. No IO cell is formed in the peripheral region 7.

In the IO region 3, provided are power lines 4 extending in the direction in which the IO cells 10 are arranged. The power lines 4 here include power lines 41 and 42 supplying VSS. Also, a power line 71 extending in the direction in which the IO cells 10 are arranged is provided in the peripheral region 7. The power line 71 here supplies VSS. While the power line 71 is illustrated as a single line, it may be constituted by a plurality of lines. Also, while illustration is omitted in FIG. 4, a plurality of external connection pads are placed in the semiconductor integrated circuit device 102.

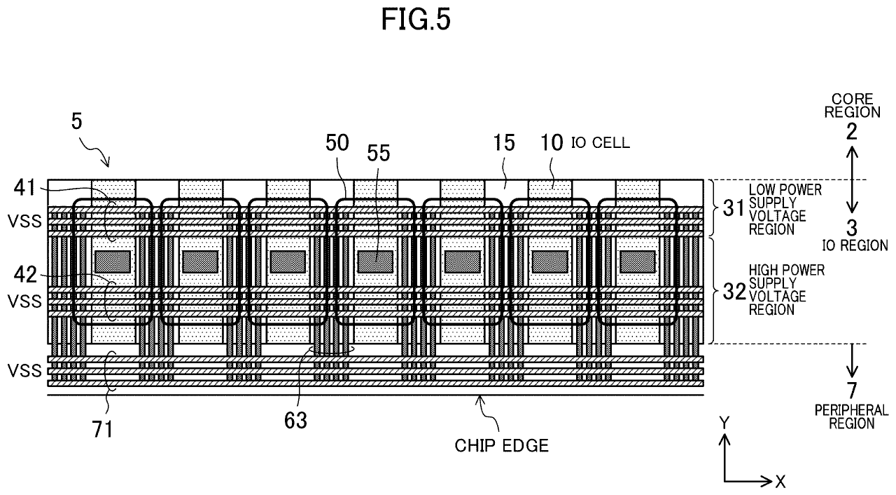

FIG. 5 is a plan view showing a configuration example of the IO region 3 and the peripheral region 7 of the semiconductor integrated circuit device 102 of this embodiment, which is an enlarged view of a part W2 of FIG. 4. Note that, in FIG. 5, illustration of the internal configuration of each IO cell 10, signal lines, and the like is omitted.

In the IO region 3, the power lines 41 and 42 extending in the X direction are placed. The power lines 41 and 42 are formed in a first interconnect layer made of a single layer or a plurality of layers, and supply VSS. While each of the power lines 41 and 42 is illustrated here as being constituted by three lines, the configuration is not limited to this. The power line 41 is placed in the low power supply voltage region 31 of each IO cell 10, and the power line 42 is placed in the high power supply voltage region 32 of each IO cell 10.

In the peripheral region 7, the power line 71 extending in the X direction is placed. The power line 71 is formed in the same first interconnect layer as the power lines 41 and 42, and supplies VSS. While the power line 71 is illustrated here as being constituted by three lines, the configuration is not limited to this. Note that the power line 71 may be formed in an interconnect layer located above or below the first interconnect layer.

A power line 63 extending in the Y direction is placed in each of the gaps 15 between the adjacent IO cells 10 in the IO region 3. The power lines 63 are formed in a second interconnect layer made of a single layer or a plurality of layers, located below the first interconnect layer. While each of the power lines 63 is illustrated here as being constituted by four lines, the configuration is not limited to this. The power lines 63 have overlaps with the external connection pads 50 in planar view. The power lines 63 are connected to the power lines 41, 42, and 71 at their respective intersections. This connection is made through vias or through vias and interconnects.

The interconnects 55 are formed in the same second interconnect layer as the power lines 63. The interconnects 55 connect the corresponding external connection pads 50 and elements such as transistors of the corresponding IO cells 10.

In the configuration of FIG. 5, in the second interconnect layer, the interconnects 55 are placed between the adjacent power lines 63 in the X direction: i.e., each interconnect 55 is interposed between two power lines 63. Also, the power lines 63 are placed between the adjacent interconnects 55: i.e., each power line 63 is interposed between two interconnects 55.

With the configuration of FIG. 5, the following advantages are obtained.

As for VSS power lines, the power line 71 supplying VSS is provided in the peripheral region 7. The power lines 41 and 42 provided in the IO region 3 and the power line 71 in the peripheral region 7 are mutually connected by the power lines 63 extending in the Y direction. With this, enhancement of the VSS power lines is achieved, whereby the resistance value of the VSS power lines can be reduced. In the semiconductor integrated circuit device 102, therefore, the power supply voltage drop can be prevented or reduced, and the ESD tolerance can be improved.

The above enhancement of the power lines is achieved by placing the power lines 63 in the gaps 15 between the adjacent IO cells 10 to connect the power lines 41, 42, and 71 supplying VSS. Therefore, no increase in the area of the semiconductor integrated circuit device 102 is caused by the placement of the power lines 63.

Also, in the configuration of FIG. 5, a large current flowing to the power line 42 in the high power supply voltage regions 32, in particular, of the IO cells 10 can be passed dispersedly to the power line 71 in the peripheral region 7. Therefore, the occurrence of electromigration in the power line 42 can be prevented or reduced.

Large noise may occur at the time of simultaneous change of signals output from the signal IO cells. By enhancing the power lines as in the configuration of FIG. 5, this problem can be prevented or reduced, and therefore a malfunction of the semiconductor integrated circuit device 102 can be prevented.

Also, in the configuration of FIG. 5, in the IO cells 10, since the power line 41 placed in the low power supply voltage regions 31 and the power line 42 placed in the high power supply voltage regions 32 are mutually connected, power enhancement inside the IO cells 10 is also achieved.

Moreover, since the power line 71 is placed near the high power supply voltage region 32 in which circuits for ESD protection are placed, ESD protection can be achieved more effectively.

<Alteration>

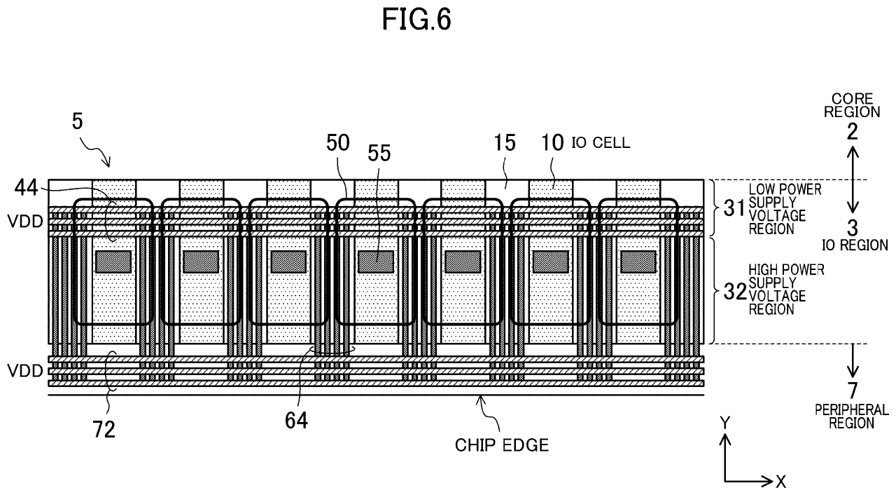

FIG. 6 is a plan view showing a configuration example of the IO region 3 of a semiconductor integrated circuit device 102 according to an alteration of this embodiment. In FIG. 6, power VDD is enhanced with a power line in the peripheral region 7.

In the IO region 3, a power line 44 extending in the X direction is placed. The power line 44 is formed in a first interconnect layer made of a single layer or a plurality of layers, and supplies VDD. While the power line 44 is illustrated here as being constituted by three lines, the configuration is not limited to this. The power line 44 is placed in the low power supply voltage region 31 of each IO cell 10.

In the peripheral region 7, a power line 72 extending in the X direction is placed. The power line 72 is formed in the same first interconnect layer as the power line 44, and supplies VDD. While the power line 72 is illustrated here as being constituted by three lines, the configuration is not limited to this. Note that the power line 72 may be formed in an interconnect layer located above or below the first interconnect layer.

A power line 64 extending in the Y direction is placed in each of the gaps 15 between the adjacent IO cells 10 in the IO region 3. The power lines 64 are formed in a second interconnect layer made of a single layer or a plurality of layers, located below the first interconnect layer. While each of the power lines 64 is illustrated here as being constituted by four lines, the configuration is not limited to this. The power lines 64 have overlaps with the external connection pads 50 in planar view. The power lines 64 are connected to the power lines 44 and 72 at their respective intersections. This connection is made through vias or through vias and interconnects.

In this alteration, also, similar advantages to those described in the above embodiment are obtained. That is, enhancement of the VDD power lines is achieved, whereby the resistance value of the VDD power lines can be reduced. In the semiconductor integrated circuit device 102, therefore, the power supply voltage drop can be prevented or reduced, and the ESD tolerance can be improved.

Note that it is also possible to perform both the enhancement of the VSS power lines in the above embodiment and the enhancement of the VDDIO power lines in this alteration together.

### OTHER EMBODIMENTS

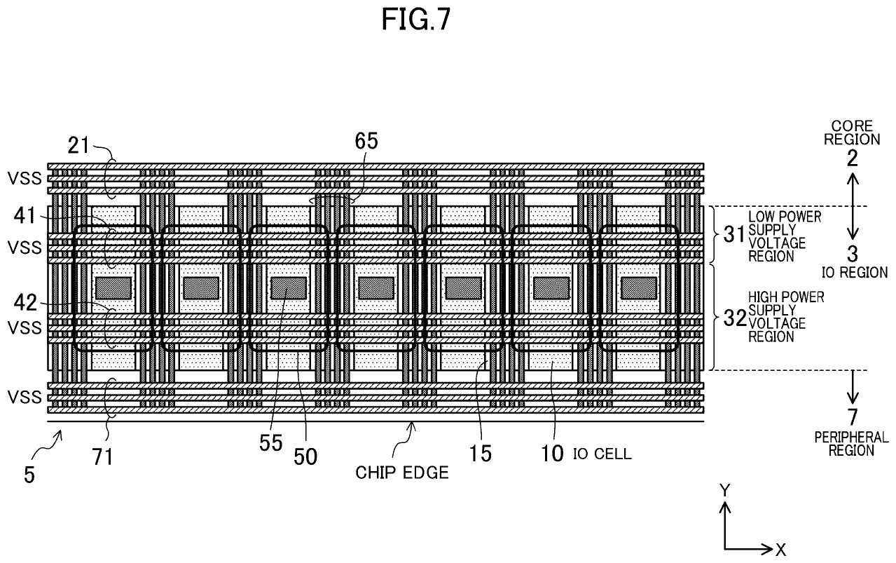

FIG. 7 shows a configuration example implemented by combining the first and second embodiments. In the configuration example of FIG. 7, the power lines 41 and 42 extending in the X direction are placed in the IO region 3. The power line 21 extending in the X direction is placed in the core region 2, and the power line 71 extending in the X direction is placed in the peripheral region 7. A power line 65 extending in the Y direction is placed in each of the gaps 15 between the adjacent IO cells 10 in the IO region 3. The power lines 65 are connected to the power lines 21, 41, 42, and 71 at their respective intersections.

With the configuration example of FIG. 7, similar advantages to those described in the first and second embodiments are obtained. While FIG. 7 illustrates the example of enhancing the VSS power lines, configurations may also be made to enhance VDD power lines and VDDIO power lines in similar ways. Also, enhancement of power lines may be made for a plurality of power supplies out of VSS, VDD, and VDDIO.

In the above embodiments, while the power lines for reinforcement extending in the Y direction are placed in the gaps 15 between the adjacent IO cells 10 in the IO region 3, the present disclosure is not limited to this. For example, the cell width of the IO cells 10 may be made large, so that power lines for reinforcement may be placed inside the IO cells 10.

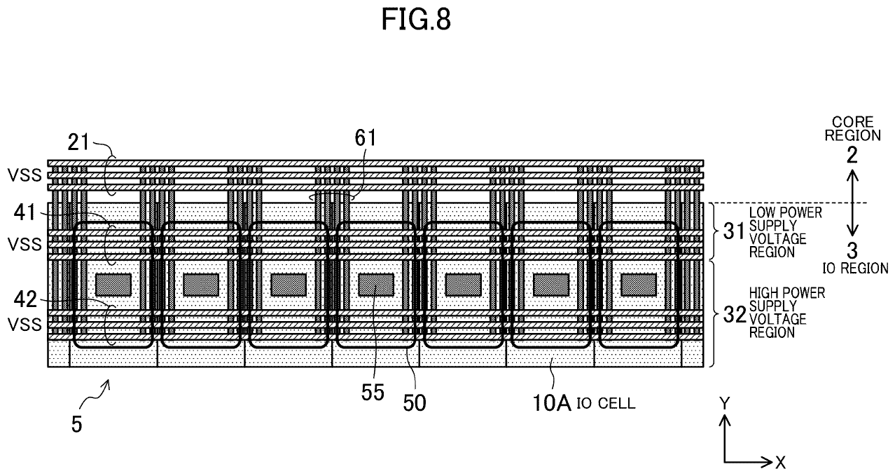

FIG. 8 shows an example altered from the configuration example of FIG. 2 so that the power lines 61 for reinforcement are provided inside IO cells 10A. In the configuration example of FIG. 8, the power lines 61 may just be regarded as lines included in the IO cells 10A at the time of design. In this case, with no need to provide lines separately, the number of design man-hours can be reduced. On the other hand, in the configuration example of FIG. 2, the power lines 61 may be regarded as lines that are not included in the IO cells 10, and may be disposed separately at the time of design. In this case, since the line width can be adjusted as required, the design flexibility improves.

Note that, in the above-described embodiments, the IO cell row 5 may be placed over the entire peripheral portion of the semiconductor integrated circuit device 100, 102, or may be placed in a part of the peripheral portion of the semiconductor integrated circuit device 100, 102. Also, the configuration in each of the above embodiments does not necessarily need to be applied to the entire of the IO cell row 5, but may just be applied to a part thereof.

According to the present disclosure, in a semiconductor integrated circuit device having an arrangement of IO cells, it is possible to enhance power lines while preventing or reducing an increase in area. The present disclosure is therefore useful for improving the performance of an LSI, for example.

1. A semiconductor integrated circuit device, comprising:
a chip;
a core region provided on the chip;
an IO region provided on the chip between the core region and an outer periphery of the chip;
an IO cell row provided in the IO region and constituted by a plurality of IO cells including first and second IO cells arranged in line in a first direction, the first direction being a direction along the outer periphery;
a first power line extending in the first direction in the IO region, formed in a first interconnect layer and supplying first power;
a second power line extending in the first direction in the core region and supplying the first power;
a third power line extending in a second direction vertical to the first direction, formed in a second interconnect layer located below the first interconnect layer and connected to the first and second power lines;
first and second external connection pads respectively corresponding to the first and second IO cells;
a first interconnect connecting the first IO cell and the first external connection pad, formed in the second interconnect layer; and
a second interconnect connecting the second IO cell and the second external connection pad, formed in the second interconnect layer,
wherein
the third power line overlaps the first external connection pad in planar view and is placed between the first interconnect and the second interconnect in the first direction.

2. The semiconductor integrated circuit device of claim 1, wherein
the third power line overlaps the first and second external connection pads in planar view.

3. The semiconductor integrated circuit device of claim 1, further comprising:
a fourth power line extending in the first direction in the IO region, formed in the first interconnect layer and supplying the first power.

4. The semiconductor integrated circuit device of claim 1, further comprising:
a fourth power line extending in the first direction in the IO region, formed in the first interconnect layer and supplying second power different from the first power.

5. A semiconductor integrated circuit device, comprising:
a chip;
a core region provided on the chip;
an IO region provided on the chip between the core region and an outer periphery of the chip;
an IO cell row provided in the IO region and constituted by a plurality of IO cells including a first IO cell arranged in line in a first direction, the first direction being a direction along the outer periphery;
a first power line extending in the first direction in the IO region, formed in a first interconnect layer and supplying first power;
a second power line extending in the first direction in the core region and supplying the first power;
a third power line extending in a second direction vertical to the first direction, formed in a second interconnect layer located below the first interconnect layer and connected to the first and second power lines;
a fourth power line extending in the second direction, formed in the second interconnect layer and connected to the first and second power lines;
a first external connection pad corresponding to the first IO cell; and
a first interconnect connecting the first IO cell and the first external connection pad, formed in the second interconnect layer,
wherein
the third and fourth power lines overlap the first external connection pad in planar view, and
the first interconnect is placed between the third power line and the fourth power line in the first direction.

6. The semiconductor integrated circuit device of claim 5, further comprising:
a fifth power line extending in the first direction in the IO region, formed in the first interconnect layer and supplying the first power.

7. The semiconductor integrated circuit device of claim 5, further comprising:
a fifth power line extending in the first direction in the IO region, formed in the first interconnect layer and supplying second power different from the first power.

8. A semiconductor integrated circuit device, comprising:
a chip;
a core region provided on the chip;
an IO region provided on the chip between the core region and an outer periphery of the chip;
a peripheral region provided on the chip between the IO region and the outer periphery;
an IO cell row provided in the IO region and constituted by a plurality of IO cells including first and second IO cells arranged in line in a first direction, the first direction being a direction along the outer periphery;
a first power line extending in the first direction in the IO region, formed in a first interconnect layer and supplying first power;
a second power line extending in the first direction in the peripheral region and supplying the first power;
a third power line extending in a second direction vertical to the first direction, formed in a second interconnect layer located below the first interconnect layer and connected to the first and second power lines;
first and second external connection pads respectively corresponding to the first and second IO cells;
a first interconnect connecting the first IO cell and the first external connection pad, formed in the second interconnect layer; and
a second interconnect connecting the second IO cell and the second external connection pad, formed in the second interconnect layer,
wherein
the third power line overlaps the first external connection pad in planar view and is placed between the first interconnect and the second interconnect in the first direction.

9. The semiconductor integrated circuit device of claim 8, wherein
the third power line overlaps the first external connection pad and the second external connection pad in planar view.

10. The semiconductor integrated circuit device of claim 8, further comprising:
a fourth power line extending in the first direction in the IO region, formed in the first interconnect layer and supplying the first power.

11. The semiconductor integrated circuit device of claim 8, further comprising:
a fourth power line extending in the first direction in the IO region, formed in the first interconnect layer and supplying second power different from the first power.

12. A semiconductor integrated circuit device, comprising:
a chip;
a core region provided on the chip;
an IO region provided on the chip between the core region and an outer periphery of the chip;
a peripheral region provided on the chip between the IO region and the outer periphery;
an IO cell row provided in the IO region and constituted by a plurality of IO cells including a first IO cell arranged in line in a first direction, the first direction being a direction along the outer periphery;
a first power line extending in the first direction in the IO region, formed in a first interconnect layer and supplying first power;
a second power line extending in the first direction in the peripheral region and supplying the first power;
a third power line extending in a second direction vertical to the first direction, formed in a second interconnect layer located below the first interconnect layer and connected to the first and second power lines;
a fourth power line extending in the second direction, formed in the second interconnect layer and connected to the first and second power lines;
a first external connection pad corresponding to the first IO cell; and
a first interconnect connecting the first IO cell and the first external connection pad, formed in the second interconnect layer,
wherein
the third and fourth power lines overlap the first external connection pad in planar view, and
the first interconnect is placed between the third power line and the fourth power line in the first direction.

13. The semiconductor integrated circuit device of claim 12, further comprising:
a fifth power line extending in the first direction in the IO region, formed in the first interconnect layer and supplying the first power.

14. The semiconductor integrated circuit device of claim 12, further comprising:
a fifth power line extending in the first direction in the IO region, formed in the first interconnect layer and supplying second power different from the first power.
